(19) United States
(12) Patent Application Publication
(10) Pub. No.: US 2010/0038642 A1
(43) Pub. Date: Feb. 18, 2010

(54) THIN FILM TRANSISTOR ARRAY PANEL AND METHOD OF MANUFACTURING THE SAME

(76) Inventors: Myoung-Wook CHOI, Suwon-si (KR); Ki-Wan Ahn, Goyang-si (KR); Dong-Seong Koo, Suwon-si (KR); In-Kyung Yoo, Yongin-si (KR); Jae-Hyuk Jang, Seoul (KR); Hun Yoo, Suwon-si (KR); Hyun-Jae Ahn, Yongin-si (KR)

Correspondence Address: F. CHAU & ASSOCIATES, LLC, 130 WOODBURY ROAD, WOODBURY, NY, 11797, US

(21) Appl. No.: 12/405,619

(22) Filed: Mar. 17, 2009

(30) Foreign Application Priority Data
Aug. 18, 2008 (KR) 10-2008-0080482

(51) Int. Cl. H01L 29/04; H01L 21/84

(52) U.S. Cl. 257/59; 438/151; 257/E29.002; 257/E21.411

(57) ABSTRACT

A thin film transistor (TFT) array panel includes a substrate, a first signal line disposed on the substrate, a first insulating layer disposed on the first signal line, a second signal line disposed on the first insulating layer, a second insulating layer disposed on the second signal line, the second insulating layer comprising an organic layer, a connection bridge disposed on the second insulating layer, the connection bridge connecting the first signal line with the second signal line, an overcoat disposed on the connection bridge, a first contact hole formed in the first and second insulating layers, the first contact hole exposing a portion of the first signal line, and a second contact hole formed in the second insulating layer, the second contact hole exposing a portion of the second signal line, wherein the connection bridge connects the first and second signal lines through the first and second contact holes.

### CROSS-REFERENCE TO RELATED APPLICATION

This application claims priority to Korean Patent Application No. 10-2008-0080482 filed on Aug. 18, 2008, the entire contents of which are incorporated herein by reference.

### BACKGROUND OF THE INVENTION

(a) Technical Field

The present disclosure relates to a thin film transistor array panel and a manufacturing method thereof, and more particularly to a thin film transistor array panel having a connection bridge connecting signal lines and a manufacturing method thereof.

(b) Discussion of the Related Art

A thin film transistor (TFT) array panel is used as a circuit substrate for independently driving each pixel in a liquid crystal display (LCD) or an organic light emitting diode (OLED) display.

In the TFT array panel, signal lines including a plurality of gate lines for transmitting gate signals and a plurality of data lines for transmitting data voltages, and a plurality of pixel electrodes connected to the signal lines, are arranged in matrix.

A display device displays an image by applying individual voltages to individual pixel electrodes. For this, TFTs, which are three-terminal elements, are respectively connected to the gate lines, the data lines, and the pixel electrodes to switch the data voltages applied to the pixel electrodes. A TFT is a switching element that transmits or blocks data voltages in response to gate signals. The data voltages are transmitted to the pixel electrodes through the data lines, and the gate signals are transmitted through the gate lines.

The TFT array panel includes a storage electrode line for maintaining the data voltages applied to the pixel electrodes, for example, after the TFTs are turned off. The storage electrode line receives a predetermined voltage such as a common voltage from outside of a pixel area of the TFT array panel. The common voltage line and the storage electrode line disposed in two different conductor layers need to be connected.

In a TFT array panel, a thick organic layer is disposed between the data lines and the pixel electrodes to prevent display deterioration due to parasitic capacitances generated between the data lines and the pixel electrodes.

### SUMMARY OF THE INVENTION

According to an exemplary embodiment of the present invention, a thin film transistor (TFT) array panel comprises a substrate, a first signal line disposed on the substrate, a first insulating layer disposed on the first signal line, a second signal line disposed on the first insulating layer, a second insulating layer disposed on the second signal line, the second insulating layer comprising an organic layer, a connection bridge disposed on the second insulating layer, the connection bridge connecting the first signal line with the second signal line, an overcoat disposed on the connection bridge, a first contact hole formed in the first and second insulating layers, the first contact hole exposing a portion of the first signal line, and a second contact hole formed in the second insulating layer, the second contact hole exposing a portion of the second signal line, wherein the connection bridge connects the first and second signal lines through the first and second contact holes.

The overcoat may comprise an inorganic material.

The inorganic material may comprise at least one of silicon oxide and silicon nitride.

The second insulating layer may further comprise an inorganic layer disposed under the organic layer.

A thickness of the organic layer can be greater than about 2 μm.

The connection bridge may comprise at least one of Indium Tin Oxide (ITO) and Indium Zinc Oxide (IZO).

The first and second signal lines may transmit a common voltage.

The TFT array panel may further comprise a gate line transmitting a gate signal, the gate line comprising a gate pad, a data line insulatively crossing the gate line and transmitting a data voltage, the data line comprising a data pad, a TFT connected to the gate line and the data line, a pixel electrode connected to the TFT, the pixel electrode receiving the data voltage from the TFT, a first contact assistant connected to the gate pad, and a second contact assistant connected to the data pad, wherein the pixel electrode and the first and second contact assistants are disposed in a same layer as the connection bridge.

The overcoat may have substantially the same planar shape as the connection bridge.

According to an exemplary embodiment of the present invention, a method of manufacturing a thin film transistor (TFT) array panel includes forming a first signal line on a substrate, forming a first insulating layer on the first signal line, forming a second signal line on the first insulating layer, forming a second insulating layer comprising an organic layer on the second signal line, forming a first contact hole in the first and second insulating layers, the first contact hole exposing a portion of the first signal line, forming a second contact hole in the second insulating layer, the second contact hole exposing a portion of the second signal line, forming a connection bridge on the second insulating layer using a first photomask, the connection bridge connecting the first and second signal lines through the first and second contact holes, and forming an overcoat on the connection bridge using the first photomask.

Forming the connection bridge and forming the overcoat may comprise depositing a transparent conductive layer and an inorganic insulating layer on the second insulating layer, coating a photosensitive film on the inorganic insulating layer, exposing the photosensitive film to light using the first photomask to form a first photosensitive film pattern comprising a first portion and a second portion, the second portion being thinner than the first portion, etching the inorganic insulating layer using the first photosensitive film pattern as an etching mask to form an intermediate inorganic insulating layer, removing the second portion of the first photosensitive film pattern to form a second photosensitive film pattern, etching the transparent conductive layer using the second photosensitive film pattern and the intermediate inorganic insulating layer as an etching mask, etching the intermediate inorganic insulating layer to remove the intermediate inorganic insulating layer not covered by the second photosensitive film pattern, and removing the second photosensitive film pattern.

The first photomask may comprise a transparent part transmitting light, an opaque part blocking light, and a translucent part partially transmitting light.

The translucent part may comprise at least one of a slit pattern, a lattice pattern, and a translucent film.

Forming the first signal line may comprise forming a gate line comprising a gate pad, forming the second signal line comprising forming a data line having a data pad and a drain electrode on the first insulating layer, forming a semiconductor on the data line and the drain electrode, and forming an ohmic contact on the semiconductor, and forming the connection bridge and the overcoat comprises forming a pixel electrode connected to the drain electrode, a first contact assistant connected to the gate pad, and a second contact assistant connected to the data pad.

Forming the data line, the drain electrode, the semiconductor, and the ohmic contact together with the second signal line may comprise using a second photomask.

The second photomask may comprise a transparent part transmitting light, an opaque part blocking light, and a translucent part partially transmitting light.

The ohmic contact, the second signal line, the data line, and the drain electrode may have substantially the same planar shape.

The overcoat may comprise an inorganic material.

The inorganic material may comprise at least one of silicon oxide and silicon nitride.

Forming the second insulating layer may further comprise depositing an inorganic layer before coating of the organic layer.

A thickness of the organic layer may be greater than about 2 μm.

Forming the connection bridge may comprise depositing Indium Tin Oxide (ITO) or Indium Zinc Oxide (IZO).

### BRIEF DESCRIPTION OF THE DRAWINGS

Exemplary embodiments of the present invention can be understood in more detail from the following descriptions taken in conjunction with the accompanying drawings, in which:

FIG. 1 is a layout view of a portion of a wiring in a thin film transistor (TFT) array panel according to an exemplary embodiment of the present invention;

FIG. 2 is a cross-sectional view taken along the line II-II in FIG. 1 according to an exemplary embodiment of the present invention;

FIG. 3 is a layout view of a pixel in a TFT array panel according to an exemplary embodiment of the present invention;

FIG. 4 is a cross-sectional view taken along the lines IV-IV′ and IV′-IV″ in FIG. 3 according to an exemplary embodiment of the present invention; and

FIG. 5 to FIG. 19 are views showing a method of manufacturing a TFT array panel for a display device according to an exemplary embodiment of the present invention.

### DESCRIPTION OF EXEMPLARY EMBODIMENTS

The present invention will be described more fully hereinafter with reference to the accompanying drawings, in which exemplary embodiments of the invention are shown. This invention may, however, be embodied in many different forms and should not be construed as limited to the exemplary embodiments set forth herein.

It will be understood that when an element such as a layer, film, region, or substrate is referred to as being “on” another element, it can be directly on the other element or intervening elements may also be present.

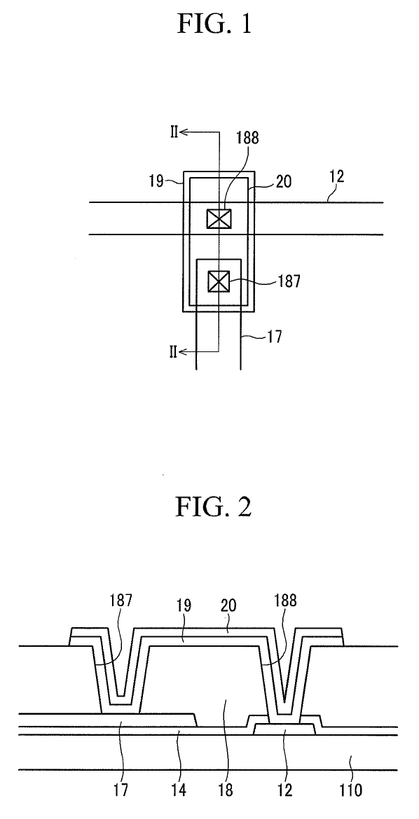

With reference to FIG. 1 and FIG. 2, a portion of wiring in a thin film transistor (TFT) array panel according to an exemplary embodiment of the present invention is described.

FIG. 1 is a layout view of a portion of a wiring in a TFT array panel according to an exemplary embodiment of the present invention. FIG. 2 is a view taken along the line II-II in FIG. 1.

Referring to FIG. 1 and FIG. 2, a lower conductive layer 12 is disposed on an insulation substrate 110 that may comprise transparent glass or plastic. The lower conductive layer 12 may comprise, for example, an aluminum-based metal such as aluminum (Al) or aluminum alloys, a silver-based metal such as silver (Ag) or silver alloys, a copper-based metal such as copper (Cu) or copper alloys, a molybdenum-based metal such as molybdenum (Mo) or molybdenum alloys, chromium (Cr), tantalum (Ta), or titanium (Ti).

An insulating layer 14 is disposed on the lower conductive layer 12. An upper conductive layer 17 is formed on the insulating layer 14. The upper conductive layer 17 may comprise, for example, an aluminum-based metal, a silver-based metal, a copper-based metal, a molybdenum-based metal, chromium (Cr), tantalum (Ta), or titanium (Ti).

A passivation layer 18 is formed on the insulating layer 14 and the lower conductive layer 12. The passivation layer 18 may comprise, for example, an organic insulator, and may have a flat surface.

A contact hole 187 that exposes the upper conductive layer 17 is formed in the passivation layer 18. A contact hole 188 that exposes the lower conductive layer 12 is formed in the passivation layer 18 and the insulating layer 14.

A pixel electrode layer 19 is formed on the passivation layer 18. The pixel electrode layer 19 is physically and electrically connected to the lower and upper conductive layers 12 and 17 through the contact holes 187 and 188.

The pixel electrode layer 19 may comprise a transparent conductive material such as indium tin oxide (ITO) or indium zinc oxide (IZO), or a reflective metal such as aluminum, silver, chromium, or alloys thereof.

A protection cover layer 20 is disposed on the pixel electrode layer 19. The protection cover layer 20 may comprise an inorganic insulator such as silicon nitride (SiNx) or silicon oxide (SiOx). The protection cover layer 20 protects the pixel electrode layer 19 from chemical or physical influences by other layers or from the outside.

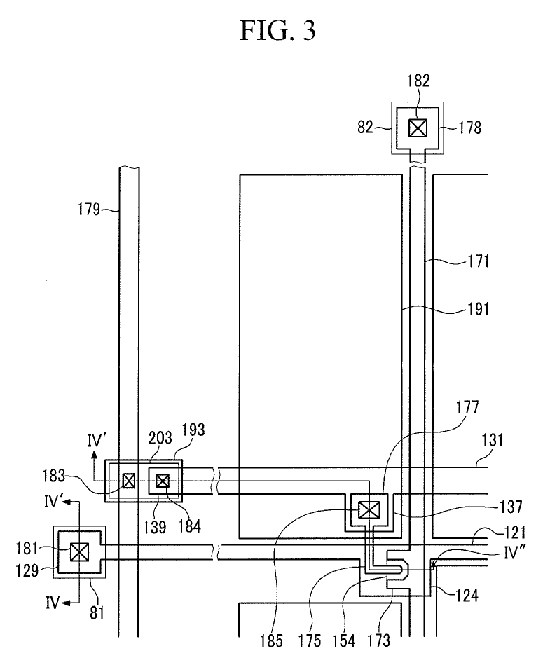

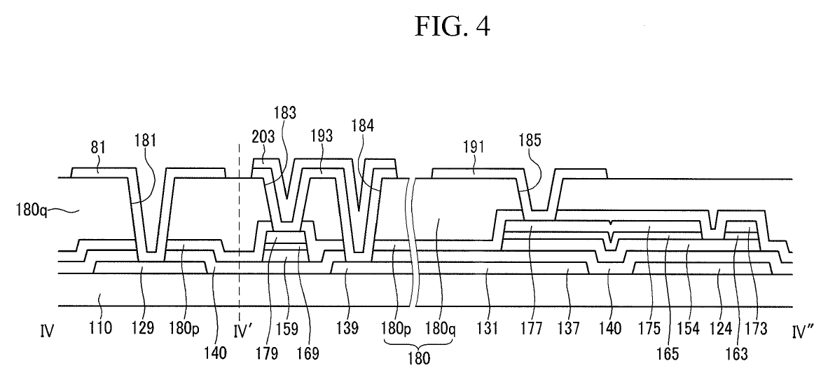

With reference to FIG. 3 and FIG. 4, a TFT array panel for a display device according to an exemplary embodiment of the present invention is described.

FIG. 3 is a layout view of a pixel of a TFT array panel for a display device according to an exemplary embodiment of the present invention. FIG. 4 is a view taken along the line IV-IV′ and IV′-IV″ in FIG. 3.

Referring to FIG. 3 and FIG. 4, a plurality of gate conductors, including a plurality of gate lines 121 and a plurality of storage electrode lines 131, are disposed on the insulation substrate 110 that may comprise transparent glass or plastic.

The gate lines 121 transmit gate signals and substantially extend in a horizontal direction, and each gate line 121 includes a plurality of gate electrodes 124 protruding downward and a wide end portion 129 for connection with other layers or a gate driving unit. When the gate driving unit is integrated on the insulation substrate 110, the gate line 121 may be extended and directly connected to the gate driving unit.

The storage electrode line 131 receives a predetermined voltage such as a common voltage Vcom and substantially extends in parallel with the gate line 121. The storage electrode line 131 includes a plurality of storage electrodes 137 protruding downward, and an end portion 139. Each storage electrode line 131 is disposed between two neighboring gate lines 121, and is closer to the lower gate line among the two gate lines 121.

The gate conductors (the gate lines 121 and the storage electrode line 131) may comprise a low resistance metal such as an aluminum-based metal including aluminum or an aluminum alloy, a silver-based metal including silver or a silver alloy, and a copper-based metal including copper or a copper alloy. Alternatively, the gate conductors 121 and 131 may have a multilayer structure including at least two conductive layers each having different physical characteristics. However, the gate conductors 121 and 131 may comprise various other metals or conductors.

A gate insulating layer 140 that may comprise silicon nitride (SiNx) or silicon oxide (SiOx) is disposed on the gate conductors 121 and 131.

On the gate insulating layer 140, a plurality of first semiconductor stripes and second semiconductor stripes 159 are disposed. The semiconductor stripes may comprise hydrogenated amorphous silicon (“a-Si”) or polysilicon. The first semiconductor stripes substantially extend in a vertical direction, and include a plurality of protrusions 154 extending toward the gate electrodes 124. The second semiconductor stripes 159 are disposed at an edge of the TFT array panel, and substantially extend in the vertical direction.

A plurality of first ohmic contact stripes, ohmic contact islands 165, and second ohmic contact stripes 169 are disposed on the semiconductors 154 and 159. Each first ohmic contact stripe has a plurality of protrusions 163. The protrusions 163 and the ohmic contact islands 165 face each other with respect to the gate electrodes 124 and are disposed on the protrusions 154 in pairs. The ohmic contacts 163, 165, and 169 may comprise a material such as n+ hydrogenated amorphous silicon in which n-type impurities such as phosphorus are doped with a high concentration. The ohmic contacts 163, 165 and 169 may comprise silicide.

Data conductors including a plurality of data lines 171, a plurality of drain electrodes 175, and a common voltage line 179 are disposed on the ohmic contacts 163, 165, and 169.

The data lines 171 transmit data signals and substantially extend in the vertical direction so that the data lines 171 insulatively cross the gate lines 121 and the storage electrode lines 131. Each data line 171 includes a plurality of source electrodes 173 that extend toward the gate electrodes 124 and a wide end portion 178 for connection with another layer or an external driver. When the data driver is integrated on the insulation substrate 110, the data line 171 may be extended to be directly connected thereto.

The drain electrode 175 faces the source electrode 173 with respect to the gate electrode 124, and includes a wide end portion 177 and a bar-shaped end portion. The wide end portion 177 overlaps the storage electrode 137 of the storage electrode line 131, and the bar-shaped end portion is partially enclosed by the source electrode 173.

The common voltage line 179 transmits a common voltage Vcom and substantially extends in the vertical direction. The common voltage line 179 is disposed at an edge of the TFT array panel and is close to the end portion 139 of the storage electrode line 131.

The data conductors 171, 175, and 179 may comprise a refractory metal such as molybdenum, chromium, tantalum, and titanium, or alloys thereof, and may have a multi-layered structure including a refractory metal layer and a low resistance conductive layer. Alternatively, like the gate conductors 121 and 131, the data conductors 171, 175 and 179 may comprise a metal having low resistance such as an aluminum-based metal, a silver-based metal, or a copper-based metal. A gate electrode 124, a source electrode 173, and a drain electrode 175, together with a protrusion 154 of the first semiconductor stripe, form a TFT. A channel of the TFT is formed in the protrusion 154 between the source electrode 173 and the drain electrode 175.

The protrusion 154 of the first semiconductor stripe has an exposed portion that is not covered by the data line 171, the drain electrode 175, and the ohmic contacts 163 and 165, such as the portion between the source electrode 173 and the drain electrode 175. That is, the semiconductors 154 and 159 have substantially the same planar shape as the data line 171, the drain electrode 175, the common voltage line 179, and the underlying ohmic contacts 163, 165, and 169, except for the protrusion 154 where the TFT is located. The ohmic contacts 163, 165, and 169 have substantially the same planar shape and outer shape as the data lines 171, the drain electrode 175, and the common voltage line 179.

A passivation layer 180 is disposed on the data conductors 171, 175, and 179 and the exposed portion 154 of the semiconductors. The passivation layer 180 includes an inorganic passivation layer 180p that may comprise an inorganic insulator such as silicon nitride or silicon oxide, and an organic passivation layer 180q that may comprise an organic insulator. The thickness of the organic passivation layer 180q may be greater than about 2 μm. In an exemplary embodiment, the passivation layer 180 may be a single layer comprising an inorganic insulator or an organic insulator with a planar surface.

A plurality of contact holes 182, 185, and 183 that respectively expose the end portion 178 of the data line 171, the wide end portion 177 of the drain electrode 175, and a portion of the common voltage line 179 facing the end portion 139 of the storage electrode line 131 are formed in the passivation layer 180. A plurality of contact holes 181 and 184 that respectively expose the end portion 129 of the gate line 121 and the end portion 139 of the storage electrode line 131 are formed in the passivation layer 180 and the gate insulating layer 140.

On the passivation layer 180, a plurality of pixel electrodes 191, a plurality of contact assistants 81 and 82, and a plurality of connection bridges 193 are disposed. The plurality of pixel electrodes 191, the plurality of contact assistants 81 and 82, and the plurality of connection bridges 193 may comprise a transparent conductive material such as ITO or IZO, or a reflective metal such as aluminum, silver, chromium, or alloys thereof.

Each pixel electrode 191 has a rectangle shape having four main sides that are substantially parallel with the gate line 121 or data line 171. The pixel electrode 191 is physically and electrically connected to the drain electrode 175 through the contact hole 185, and receives a data voltage from the drain electrode 175.

The contact assistants 81 and 82 are respectively connected to the end portion 129 of the gate line 121 and the end portion 178 of the data line 171 through the contact holes 181 and 182. The contact assistants 81 and 82 assist the adhesion of the end portion 129 of the gate line 121 and the end portion 178 of the data line 171 to external devices, and protect the end portion 129 of the gate line 121 and the end portion 178 of the data line 171.

The connection bridge 131 physically and electrically connects the end portion 139 of the storage electrode line 131 and the common voltage line 179 through the contact holes 183 and 184. The storage electrode line 131 receives the common power Vcom from the common voltage line 179 through the connection bridge 193.

A plurality of overcoats 203 that may comprise an inorganic insulator such as silicon nitride or silicon oxide are disposed on the connection bridges 193. The overcoats 203 and the connection bridges 193 have substantially the same planar shape. The overcoats 203 protect the connection bridges 193 from, for example, external influences such as physical impact or a chemical material, and prevent corrosion of the connection bridges 193. The overcoats 203 prevent chemical reaction between the connection bridges 193 and other layers thereon to thereby prevent display deterioration such as bruising.

Since a thick organic passivation 180q is formed under the pixel electrode 191 in an exemplary embodiment, a capacitance of a coupling capacitor generated between adjacent pixel electrode 191 and data line 171 may be greatly reduced so that display deterioration such as bruising may be prevented. Accordingly, distances between pixel electrodes 191 may be reduced, thereby increasing the aperture ratio of the display device.

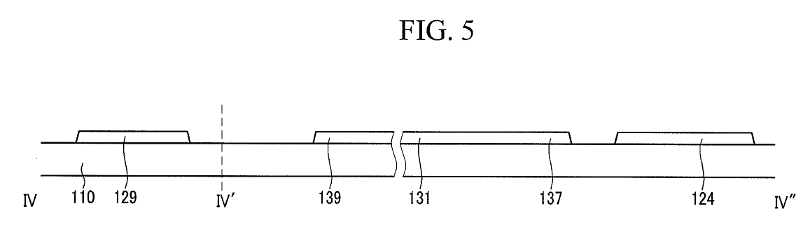

A method of manufacturing the TFT array panel of FIG. 3 and FIG. 4 according to an exemplary embodiment of the present invention is described with reference to FIG. 3, FIG. 4, and FIG. 5 to FIG. 19.

FIG. 5 to FIG. 19 are cross-sectional views of intermediate steps of a manufacturing method for the TFT array panel for a display device of FIG. 3 and FIG. 4 according to an exemplary embodiment of the present invention.

Referring to FIG. 5, a gate conductive layer that comprises a low resistance metal such as an aluminum-based metal, a silver-based metal, a cooper-based metal, a molybdenum-based metal, chromium, tantalum, and titanium is deposited by sputtering on an insulation substrate 110 that comprises transparent glass or plastic. Then, the gate conductive layer is etched by performing a photolithography process with a mask to form gate conductors 121 and 131 including a plurality of gate lines 121 and a plurality of storage electrode lines 131 on the insulation substrate 110.

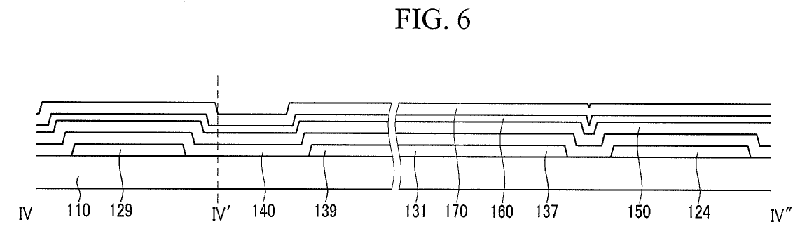

Referring to FIG. 6, a gate insulating layer 140 comprising silicon nitride or silicon oxide, an intrinsic semiconductor layer 150 comprising amorphous or crystalline silicon, and a impurity-doped semiconductor layer 160 are sequentially deposited on the gate conductors 121 and 131 using, for example, a plasma enhanced chemical vapor deposition (PECVD) process. The impurity-doped semiconductor layer 160 comprises amorphous silicon in which n-type impurities such as phosphorus are doped with high concentration, or silicide. Subsequently, a data conductive layer 170 is formed by depositing a data conductive material using, for example, a sputtering method.

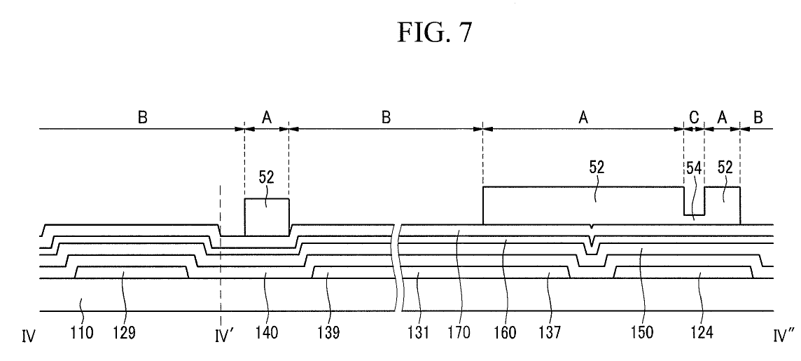

Referring to FIG. 7, a photosensitive film is coated on the data conductive layer 170. The photosensitive film is exposed to light and developed through a photomask such that a photosensitive film pattern including a thick portion 52 and a thin portion 54 is formed.

When the photosensitive film has negative photosensitivity where a portion exposed to light remains, the photomask in the A region is transparent so that light is transmitted, the photomask in the B region is opaque so that light is blocked, and the photomask in the C region is translucent so that light is partially transmitted. The photosensitive film in the A region where light is transmitted forms the thick portion 52. The photosensitive film in the B region is removed. The photosensitive film in the C region forms the thin portion 54. Alternatively, when the photosensitive film has positive photosensitivity so that a portion exposed to light is eliminated, transparency of the A and B regions are reversed and the C region is translucent.

The photomask in the C region may include a slit or lattice pattern for regulating light transmittance, or may be a translucent film. In an exemplary embodiment, the width of the slits or the gaps in the lattice pattern may be smaller than resolution of a light exposer. When a translucent film is used, the translucent film may have different transmittance or different thickness in regions A and B.

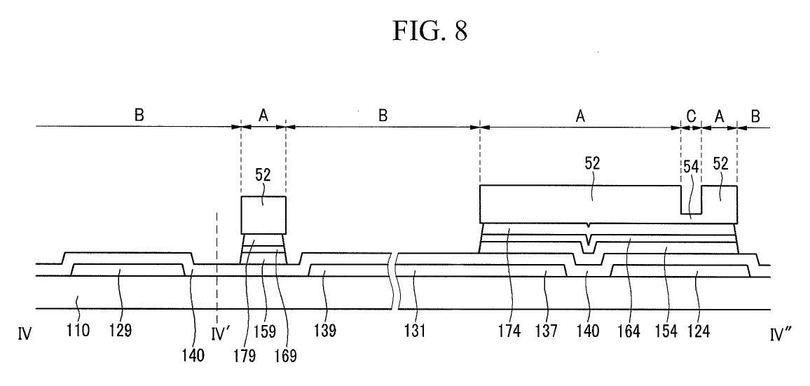

Referring to FIG. 8, the data conductive layer 170, the impurity-doped semiconductor layer 160, and the intrinsic semiconductor layer 150 in the B region are wet-etched or dry-etched using the photosensitive film pattern 52 and 54 as an etching mask. As a result, a plurality of data conductor layers 174 and 179, a plurality of ohmic contact layers 164 and 169, and a plurality of first semiconductor stripes including, protrusions 154 and a plurality of second semiconductor stripes 159, which have the same planar shape with each other, can be formed.

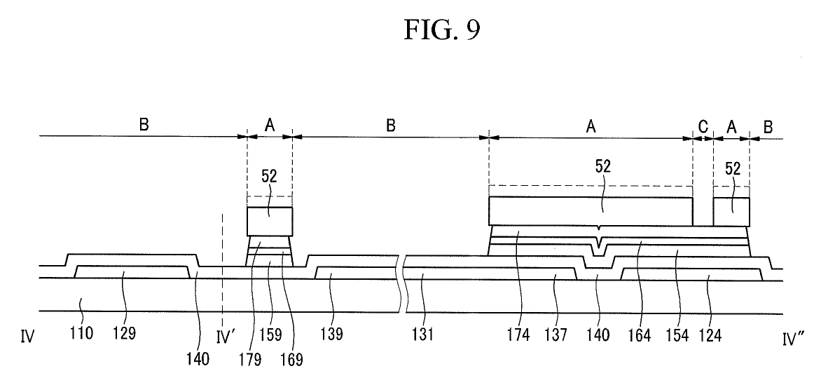

Referring to FIG. 9, the thin portions 54 of the photosensitive film pattern 52 and 54 in the C region are removed. The thick portions 52 become thinner because a portion of them is also removed as much as the thickness of the thin portion 54.

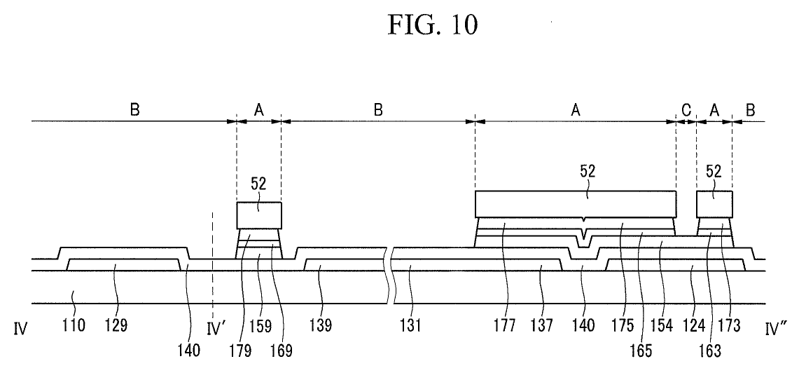

Referring to FIG. 10, a plurality of data lines 171 each including source electrodes 173, a plurality of drain electrodes 175 each including a wide end portion 177, a plurality of common voltage lines 179, a plurality of first ohmic contact stripes each including protrusions 163, a plurality of ohmic contact island 165, and a plurality of second ohmic contact stripes 169 are formed by etching the data conductor layers 174 and the ohmic contact layers 164 by using the remaining photosensitive film pattern 52.

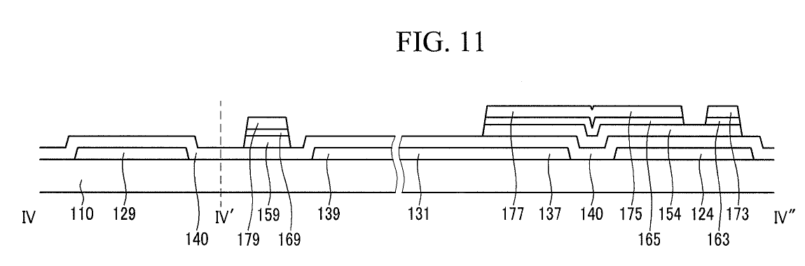

Referring to FIG. 11, the remaining photosensitive film pattern 52 is removed.

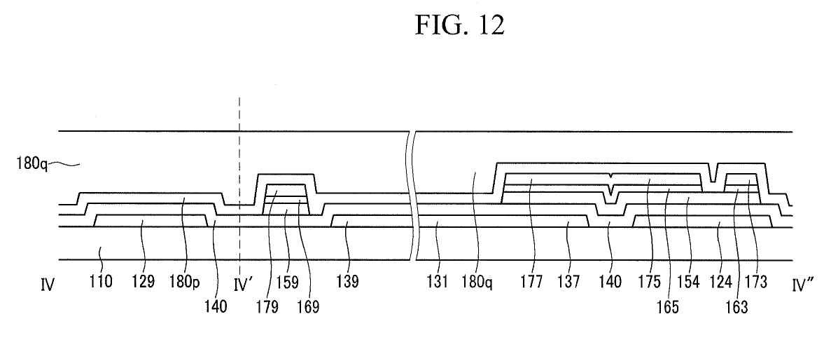

Referring to FIG. 12, an inorganic insulator is deposited and an organic layer is coated thereon such that an inorganic passivation layer 180p and an organic passivation layer 180q are formed. The thickness of the organic passivation layer 180q may be greater than 2 μm.

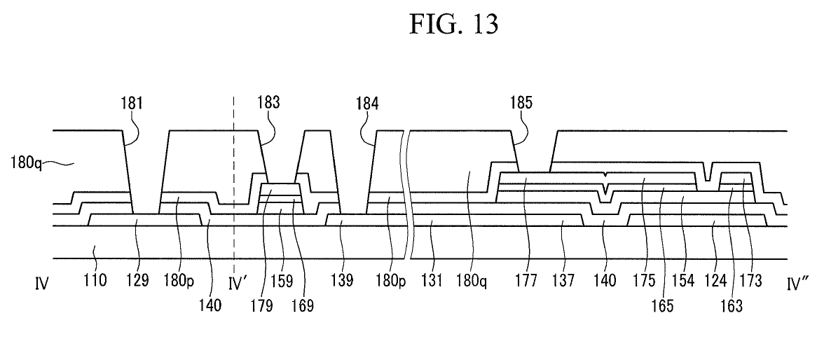

Referring to FIG. 13, a plurality of contact holes 181, 182, 183, 184, and 185 are formed by performing a photolithography on the inorganic passivation layer 180p and the organic passivation layer 180q. The gate insulating layer 140 is also etched to form the contact holes 181 and 184 that expose the end portion 129 of the gate line 121 and the end portion 139 of the storage electrode line 131.

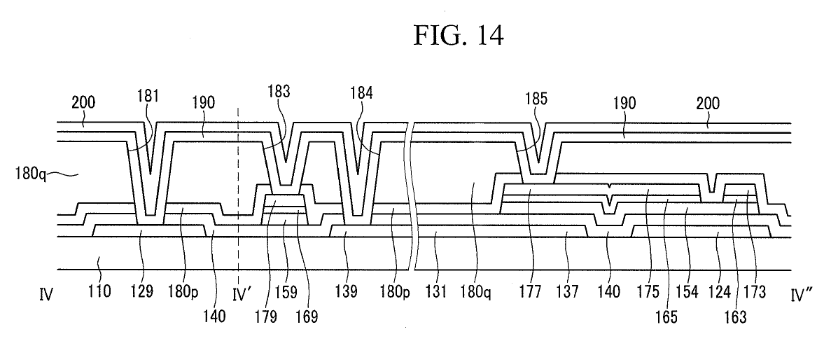

Referring to FIG. 14, a transparent conductive layer 190 that may comprise Indium Tin Oxide (ITO) or Indium Zinc Oxide (IZO) is deposited by, for example, sputtering on the organic passivation layer 180q. An inorganic insulating layer 200 comprising, for example, silicon nitride or silicon oxide is deposited on the transparent conductive layer 190.

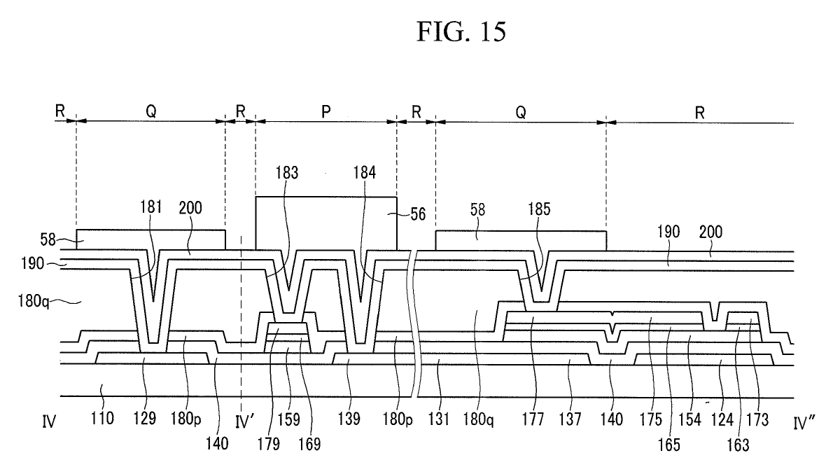

Referring to FIG. 15, a photosensitive film is coated on the inorganic insulating layer 200. The photosensitive film is exposed to light through a photomask and developed to form a photosensitive film pattern including a thin portion 58 and a thick portion 56.

When the photosensitive film has negative photosensitivity, the photomask in the P region is transparent so that light is transmitted, the photomask in the R region is opaque so that light is blocked, and the photomask in the Q region is translucent so that light is partially transmitted. A portion of the photosensitive film where light is irradiated remains and a portion of the photosensitive film where the light is blocked is removed. As such, the photosensitive film in the P region forms the thick portion 56, the photosensitive film in the R region is removed, and the photosensitive film in the Q region forms the thin portion 58. The photomask in the Q region may include a slit or lattice pattern for controlling light transmittance, or may be a translucent film.

Alternatively, when the photosensitive film has positive photosensitivity, the transparency of the photomask in the P and R regions are reversed and the photomask in the C region is translucent.

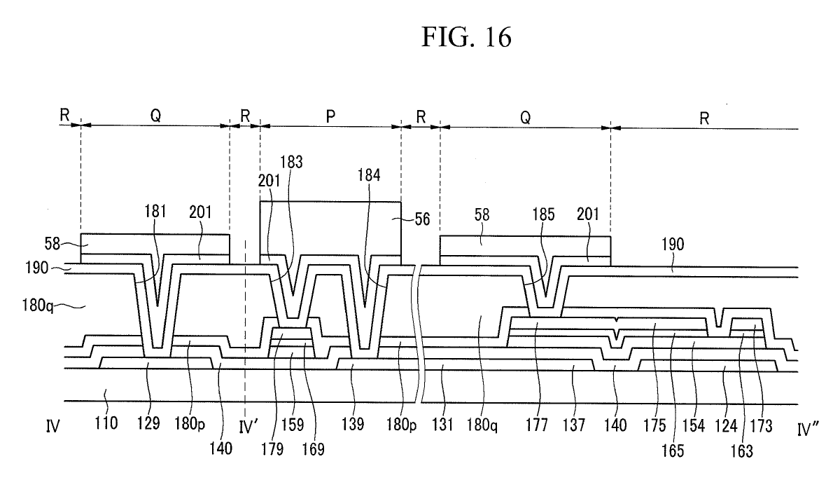

Referring to FIG. 16, the inorganic insulating layer 200 in the R region is removed by dry-etching with an etching gas such as sulfur hexafluoride (SF₆) or chlorine trifluoride (CIF₃) to form an intermediate inorganic insulating layer 201. In an exemplary embodiment, the photosensitive film pattern 56 and 58 is used as an etching mask.

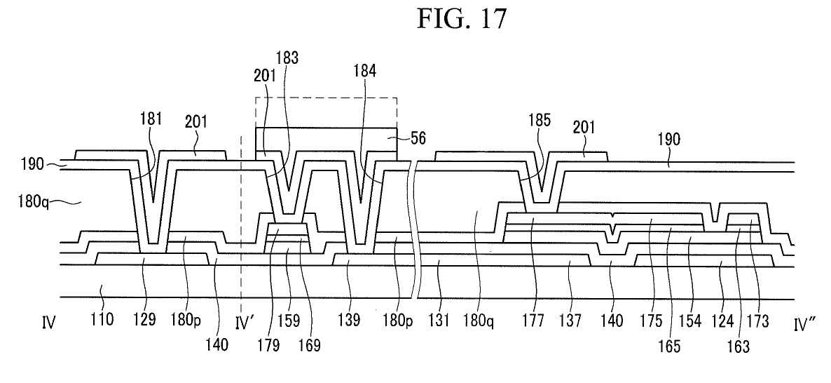

Referring to FIG. 16 and FIG. 17, the thin portion 58 of the photosensitive film pattern 56 and 58 in the Q region is removed by, for example, dry-etching using oxygen plasma O₂.

At this stage, the thick portion 56 becomes thinner since a portion thereof is eliminated as much as the thickness of the thin portion 58.

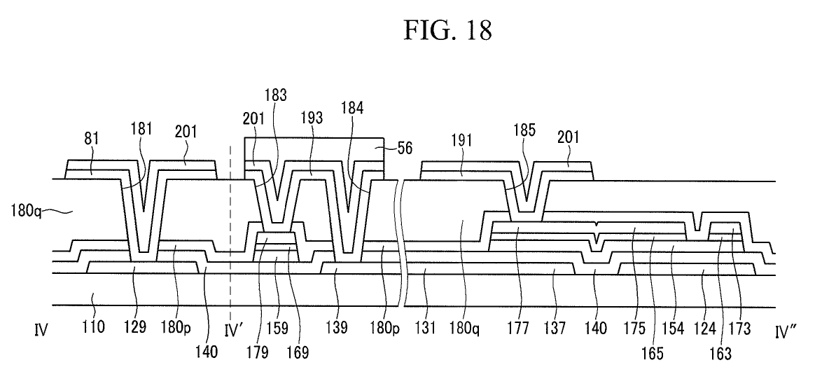

Referring to FIG. 18, the remaining photosensitive film pattern 56 and the intermediate inorganic insulating layer 201 are used as a mask in etching the transparent conductive layer 190 to form a plurality of pixel electrodes 191, a plurality of contact assistants 81 and 82, and a plurality of connection bridges 193.

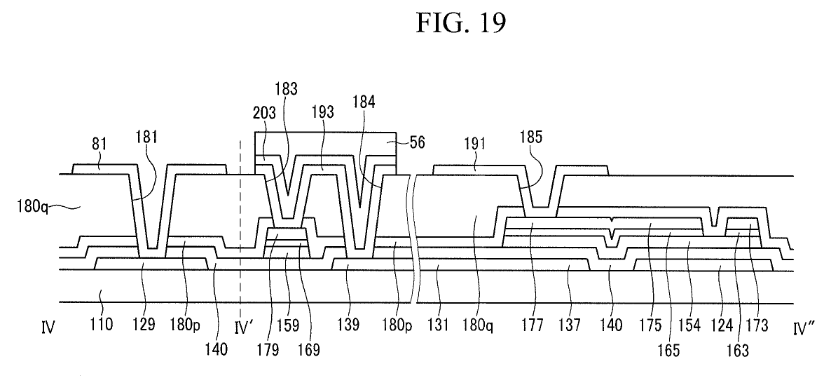

Referring to FIG. 19, the intermediate inorganic insulating layer 201 not covered by the remaining photosensitive film pattern 56, that is, the remaining intermediate inorganic insulating layer 201 on the contact assistants 81 and 82 and the pixel electrodes 191, is removed by dry-etching. As such, an overcoat 203 is disposed only on the connection bridge 193.

Referring to FIG. 4, the remaining photosensitive film pattern 56 is removed.

According to an exemplary embodiment of the present invention, data conductors 171, 175, and 179, ohmic contacts 163, 165, and 169, and semiconductors 154 and 159 are formed by using one photosensitive film pattern as an etching mask. Pixel electrodes 191, contact assistants 81 and 82, and connection bridges 193 are formed together by using another photosensitive film pattern. Accordingly, a manufacturing process of a display device becomes simplified.

According to an exemplary embodiment of the present invention, display deterioration of a display device can be prevented and the aperture ratio can be increased by using an organic layer and protecting a connection bridge of a wire with an overcoat.

Although the exemplary embodiments of the present invention have been described herein with reference to the accompanying drawings, it is to be understood that the present invention should not be limited to those precise embodiments and that various other changes and modifications may be affected therein by one of ordinary skill in the related art without departing from the scope or spirit of the invention. All such changes and modifications are intended to be included within the scope of the invention as defined by the appended claims.

What is claimed is:

1. A thin film transistor (TFT) array panel comprising:
a substrate;
a first signal line disposed on the substrate;
a first insulating layer disposed on the first signal line;
a second signal line disposed on the first insulating layer;
a second insulating layer disposed on the second signal line, the second insulating layer comprising an organic layer;
a connection bridge disposed on the second insulating layer, the connection bridge connecting the first signal line with the second signal line;
an overcoat disposed on the connection bridge;
a first contact hole formed in the first and second insulating layers, the first contact hole exposing a portion of the first signal line; and
a second contact hole formed in the second insulating layer, the second contact hole exposing a portion of the second signal line,
wherein the connection bridge connects the first and second signal lines through the first and second contact holes.

2. The TFT array panel of claim 1, wherein the overcoat comprises an inorganic material.

3. The TFT array panel of claim 2, wherein the inorganic material comprises at least one of silicon oxide and silicon nitride.

4. The TFT array panel of claim 1, wherein the second insulating layer further comprises an inorganic layer disposed under the organic layer.

5. The TFT array panel of claim 4, wherein a thickness of the organic layer is greater than about 2 μm.

6. The TFT array panel of claim 1, wherein the connection bridge comprises at least one of Indium Tin Oxide (ITO) and Indium Zinc Oxide (IZO).

7. The TFT array panel of claim 1, wherein the first and second signal lines transmit a common voltage.

8. The TFT array panel of claim 1, further comprising:
a gate line transmitting a gate signal, the gate line comprising a gate pad;
a data line insulatively crossing the gate line and transmitting a data voltage, the data line comprising a data pad;
a TFT connected to the gate line and the data line;
a pixel electrode connected to the TFT, the pixel electrode receiving the data voltage from the TFT;
a first contact assistant connected to the gate pad; and
a second contact assistant connected to the data pad,
wherein the pixel electrode and the first and second contact assistants are disposed in a same layer as the connection bridge.

9. The TFT array panel of claim 1, wherein the overcoat has substantially the same planar shape as the connection bridge.

10. A method of manufacturing a thin film transistor (TFT) array panel, comprising:
forming a first signal line on a substrate;
forming a first insulating layer on the first signal line;
forming a second signal line on the first insulating layer;
forming a second insulating layer comprising an organic layer on the second signal line;
forming a first contact hole in the first and second insulating layers, the first contact hole exposing a portion of the first signal line;
forming a second contact hole in the second insulating layer, the second contact hole exposing a portion of the second signal line;
forming a connection bridge on the second insulating layer using a first photomask, the connection bridge connecting the first and second signal lines through the first and second contact holes; and
forming an overcoat on the connection bridge using the first photomask.

11. The method of claim 10, wherein forming the connection bridge and forming the overcoat comprises:
depositing a transparent conductive layer and an inorganic insulating layer on the second insulating layer;
coating a photosensitive film on the inorganic insulating layer;
exposing the photosensitive film to light using the first photomask to form a first photosensitive film pattern comprising a first portion and a second portion, the second portion being thinner than the first portion;
etching the inorganic insulating layer using the first photosensitive film pattern as an etching mask to form an intermediate inorganic insulating layer;
removing the second portion of the first photosensitive film pattern to form a second photosensitive film pattern;
etching the transparent conductive layer using the second photosensitive film pattern and the intermediate inorganic insulating layer as an etching mask;
etching the intermediate inorganic insulating layer to remove the intermediate inorganic insulating layer not covered by the second photosensitive film pattern; and
removing the second photosensitive film pattern.

12. The method of claim 11, wherein the first photomask comprises a transparent part transmitting light, an opaque part blocking light, and a translucent part partially transmitting light.

13. The method of claim 12, wherein the translucent part comprises at least one of a slit pattern, a lattice pattern, and a translucent film.

14. The method of claim 10, wherein forming the first signal line comprises forming a gate line comprising a gate pad, forming the second signal line comprising forming a data line having a data pad and a drain electrode on the first insulating layer, forming a semiconductor on the data line and the drain electrode, and forming an ohmic contact on the semiconductor, and forming the connection bridge and the overcoat comprises forming a pixel electrode connected to the drain electrode, a first contact assistant connected to the gate pad, and a second contact assistant connected to the data pad.

15. The method of claim 14, wherein forming the data line, the drain electrode, the semiconductor, and the ohmic contact together with the second signal line comprises using a second photomask.

16. The method of claim 15, wherein the second photomask comprises a transparent part transmitting light, an opaque part blocking light, and a translucent part partially transmitting light.

17. The method of claim 15, wherein the ohmic contact, the second signal line, the data line, and the drain electrode have substantially the same planar shape.

18. The method of claim 10, wherein the overcoat comprises an inorganic material.

19. The method of claim 18, wherein the inorganic material comprises at least one of silicon oxide and silicon nitride.

20. The method of claim 10, wherein forming the second insulating layer further comprises depositing an inorganic layer before coating of the organic layer.

21. The method of claim 20, wherein a thickness of the organic layer is greater than about 2 μm.

22. The method of claim 10, wherein forming the connection bridge comprises depositing Indium Tin Oxide (ITO) and Indium Zinc Oxide (IZO).
